(19) United States
(12) Patent Application Publication
(10) Pub. No.: US 2011/0259395 A1
(43) Pub. Date: Oct. 27, 2011

(54) Single Junction CIGS/CIS Solar Module

(75) Inventors: Robert D. Wieting, Simi Valley, CA (US); Rajiv Pethe, (US); Kannan Ramanathan, (US); May Shao, (US); Ashish Tandon, (US)

(73) Assignee: Stion Corporation, San Jose, CA (US)

(21) Appl. No.: 13/086,135

(22) Filed: Apr. 13, 2011

Related U.S. Application Data
(60) Provisional application No. 61/326,315, filed on Apr. 21, 2010.

(51) Int. Cl. H01L 31/0236; H01L 31/18; H01L 27/142

(52) U.S. Cl. 136/246; 136/249; 438/71; 257/E31.13

(57) ABSTRACT

A high efficiency thin-film photovoltaic module is formed on a substrate. The photovoltaic module includes a plurality of stripe shaped photovoltaic cells electrically coupled to each other and physically disposed in parallel to the length one next to another across the width. Each cell includes a barrier material overlying the surface and a first electrode overlying the barrier material. Each cell further includes an absorber formed overlying the first electrode. The absorber includes a copper gallium indium diselenide compound material characterized by an energy band-gap of about 1 eV to 1.1 eV. Each cell additionally includes a buffer material overlying the absorber and a bi-layer zinc oxide material comprising a high resistivity transparent layer overlying the buffer material and a low resistivity transparent layer overlying the high resistivity transparent layer.

### CROSS-REFERENCE TO RELATED APPLICATION

This application claims priority to U.S. Provisional Application No. 61/326,315, titled “HIGH EFFICIENCY CIGS/CIS SOLAR MODULE”, filed Apr. 21, 2010, by Robert D. Wieting, commonly assigned, and hereby incorporated by reference in its entirety herein for all purpose.

### BACKGROUND OF THE INVENTION

This invention relates generally to a thin-film photovoltaic module and method of manufacturing it. More particularly, the invention provides a structure and method for manufacturing high efficiency thin film photovoltaic modules. The invention provides high efficiency thin film photovoltaic panels of a large size and with a single junction copper-indium-gallium diselenide (CIGS) cell having circuit photovoltaic efficiency of 12-15% or higher.

From the beginning of time, mankind has been challenged to find way of harnessing energy. Energy comes in the forms such as petrochemical, hydroelectric, nuclear, wind, biomass, solar, and more primitive forms such as wood and coal. Over the past century, modern civilization has relied upon petrochemical energy as an important energy source. Petrochemical energy includes gas and oil, including lighter forms, such as butane and propane used to heat homes and serve as fuel for cooking. Oil includes gasoline, diesel, and jet fuel, commonly used for transportation purposes. Unfortunately, the supply of petrochemical fuel is limited and essentially fixed based upon the amount available on the planet Earth. Additionally, as more people use petroleum products in growing amounts, it is rapidly becoming a scarce resource, which will eventually become depleted over time.

More recently, environmentally clean and renewable sources of energy have been desired. An example of a clean source of energy is hydroelectric power. Hydroelectric power is derived from electric generators driven by the flow of water. Clean and renewable sources of energy also include wind, waves, and biomass. Still other types of clean energy include solar energy.

Solar energy technology generally converts electromagnetic radiation from the sun into other useful forms of energy. These other forms of energy include thermal energy and electrical power. For electrical power applications, solar cells are often used. Although solar energy is environmentally clean and has been successful to a point, issues remain to be resolved before it becomes widely used throughout the world. For example, one type of solar cell uses crystalline materials, which are derived from semiconductor material ingots. These crystalline materials can be used to fabricate optoelectronic devices that include photovoltaic and photodiode devices that convert electromagnetic radiation into electrical power. Crystalline materials, however, are often costly and difficult to make on a large scale. Additionally, devices made from such crystalline materials often have low energy conversion efficiencies. Other types of solar cells use “thin film” technology to form a thin film of photosensitive material to be used to convert electromagnetic radiation into electrical power. Film reliability is often poor and cannot be used for extended time in conventional environmental applications. Often, thin films are difficult to mechanically integrate with each other.

### BRIEF SUMMARY OF THE INVENTION

According to embodiments of the present invention, a structure and a method for forming high efficiency thin-film photovoltaic module are provided. More particularly, the present invention provides high efficiency thin film photovoltaic panels of 165×65 cm or greater in size and CIGS single junction cells with a circuit photovoltaic efficiency of 12-15% and higher.

This invention provides a high efficiency thin-film photovoltaic module formed on a substrate having a surface with a length of about 2 feet and greater, and a width of about 5 feet and greater. The photovoltaic module includes a plurality of stripe shaped photovoltaic cells electrically coupled to each other and disposed in parallel to the length, one next to another across the width. Each cell includes a barrier material overlying the surface and a first electrode overlying the barrier material. Each cell further includes an absorber formed overlying the first electrode, the absorber comprising a copper gallium indium diselenide compound material characterized by an energy band-gap of about 1 eV to 1.1 eV. Additionally, each cell includes a buffer material overlying the absorber and a bi-layer zinc oxide (ZnO) material comprising a high resistivity transparent layer overlying the buffer material and a low resistivity transparent layer overlying the high resistivity transparent layer. The buffer material combining the high resistivity transparent layer forms a photovoltaic window material for collecting photoelectrons converted by the photovoltaic absorber and the low resistivity transparent layer forms a second electrode. The photovoltaic module further includes a first electric lead and a second electric lead formed respectively on the first electrode near each edge region of the substrate along the length.

In an alternative embodiment, the invention provides a method for manufacturing a high efficiency thin-film photovoltaic module. The method includes supplying a substrate of about 2 feet by 5 feet, and larger. A barrier material is formed over the substrate and a conductive material over that. Additionally, the method includes scribing through the conductive material with a substantially equal spacing to form a plurality of stripe shaped cells. The conductive material within each stripe shaped cell forms a first electrode.

The method includes forming a precursor material overlying the first electrode. The precursor material includes at least a sodium-bearing material, a copper-gallium alloy material, and an indium material. The precursor material is treated in a gaseous environment having at least a selenium species and a sulfur species to form an absorber material characterized by a p-type electrical characteristic with an energy band-gap of about 1 eV to 1.1 eV and Cu/(In+Ga) ratio of about 0.9. The method further includes forming a buffer material having n-type characteristic overlying the absorber material having the p-type characteristic to form a pn junction. Furthermore, the method includes patterning the absorber material and buffer material to couple each stripe shaped cell with a neighboring stripe shaped cell. A high resistivity transparent material is formed over the buffer material, followed by a transparent conductive material. Moreover, the method includes patterning the transparent conductive material, the buffer material, and the absorber material to form a second electrode for each stripe shaped cell.

The present invention uses a process for fabricating a thin-film photovoltaic module based on a glass substrate with a form factor of 165×65 cm and larger. Advantages over conventional thin-film module includes low cost, simplified thin-film process, high efficiency with CIGS single junction photovoltaic cells with a largest monolithic panel size, and optimized pin-stripe cell pattern for maximizing photon reception. The simplified thin-film process includes preparing basic materials directly on the large sized soda lime glass substrate, including barrier material, metallic electrode material, and one or more precursor materials. Additionally, the simplified thin-film process includes a two-step process for fabricating the high efficiency copper-indium-gallium-diselenide (CIGS) photovoltaic absorber, including forming a precursor composite film first, followed by performing a thermal reactive selenization and sulfurization treatment of the precursor composite film. A specific embodiment includes a single junction cell with the CIGS photovoltaic absorber characterized by an energy gap of about 1.0 eV and 1.1 eV. This allows the CIGS cell to serve as a bottom device mechanically coupled to a bifacial top device to form a laminated module with a combined photovoltaic circuit efficiency comparable to silicon but with a much lower cost. Other advantages include using environmentally friendly materials that are relatively less toxic than other thin-film photovoltaic materials and high temperature tolerant transparent conductive material for adapting the improved absorber thermal process and keeping reasonable optical transparency afterwards.

### BRIEF DESCRIPTION OF THE DRAWINGS

FIG. 1 is a diagram illustrating a single junction CIGS thin-film photovoltaic cell structure;

FIG. 2 is a diagram illustrating a thin-film precursor material formed overlying a back electrode;

FIG. 3 is a diagram illustrating a thin-film precursor material being treated for fabricating a photovoltaic absorber material;

FIG. 4 is a diagram illustrating a formation of the photovoltaic absorber material;

FIG. 5 is a SEM image of grain structures of CIGS thin-film photovoltaic absorber and upper electrode ZnO layer;

FIG. 6 is an IV characteristic diagram illustrating efficiency for a sample CIGS photovoltaic module;

FIG. 7 is a simplified diagram illustrating an optional application of a CIGS photovoltaic cell as a bottom device coupled with a top bi-facial device for forming a tandem module according to an embodiment of the present invention.

FIG. 8 is a schematic diagram illustrating a top view of a laminated sample CIGS photovoltaic module.

FIG. 9 is a simplified diagram of a cross sectional view and a corresponding top view of a cell structure of a single junction CIGS thin-film photovoltaic module.

### DETAILED DESCRIPTION OF THE INVENTION

A cell structure and method for forming high efficiency thin-film photovoltaic modules are provided. The invention enables a high efficiency CIGS/CIS based thin-film photovoltaic cell from which an industrial sized panel having a form factor of 165×65 cm or greater is fabricated with a circuit efficiency of 12-15% or higher. Through work on thin-film absorber composition stoicheometry and grain structure tuning, the single junction CIGS/CIS photovoltaic absorber has an optimized opto-electric property characterized by an energy bandgap in 1.0 to 1.1 eV. This enables the cell to be used as a bottom device capable of coupling with top bi-facial devices to form a multi junction module with an enhanced module efficiency. Embodiments of the present invention may be used to include other types of semiconducting thin films or multilayers comprising iron sulfide, cadmium sulfide, zinc selenide, and others, and metal oxides such as zinc oxide, iron oxide, copper oxide, and others.

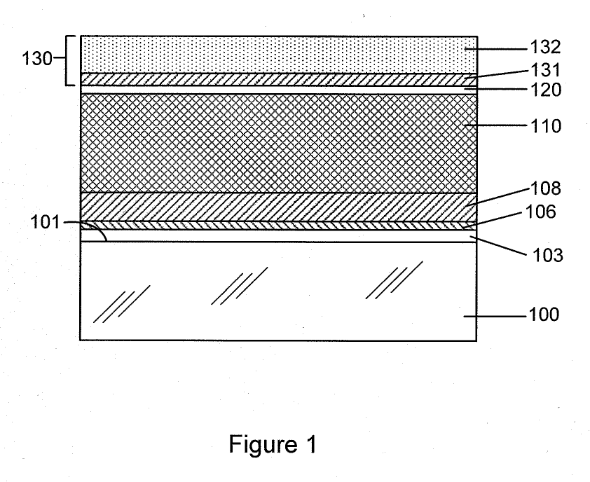

FIG. 1 is a schematic diagram illustrating a single junction CIGS thin-film photovoltaic cell structure according to an embodiment of the present invention. As shown, the present invention provides a substrate 100 for forming a thin-film photovoltaic device. In a specific embodiment, the substrate 100 has an industrial form factor of 165×65 cm and made of a material selected from soda-lime glass, acrylic glass, sugar glass, specialty Corning™ glass, quartz, and plastic. The substrate has a surface region 101 that is prepared for forming thin-film materials thereon. As shown, a barrier material 103 overlies the surface region 101. Especially for a substrate using soda lime glass material, the barrier material 103 prevents sodium ions in the soda lime glass from diffusing uncontrollably into photovoltaic material area formed in subsequent processes. Soda lime glass usually contains alkaline ions with greater than 10 wt % sodium oxide, or about 15% wt % sodium. Depending on the embodiment, the barrier material 103 can be a dielectric material selected from silicon oxide, aluminum oxide, titanium nitride, silicon nitride, tantalum oxide, and zirconium oxide deposited using technique such as sputtering, e-beam evaporation, chemical vapor deposition (including plasma enhanced processes), and others. In a specific embodiment, the thickness of the thin barrier material 103 is about 200 Angstroms or greater. In another specific embodiment, the thickness of the barrier material 103 is about 500 Angstroms and greater. Of course, alternative barrier material can be used, for example, a two-material bi-layer including oxide or nitride material.

In one embodiment, a back electrode is formed overlying the barrier material 103. The back electrode can be made of a conductive material including metal or metal alloy. In an example, molybdenum or molybdenum selenide is used. According to a specific embodiment as shown in FIG. 1, the back electrode is a bi-layer structure comprising a first molybdenum layer 106 and a second molybdenum layer 108. The first molybdenum layer 106 is formed overlying the barrier material 103 via a low-pressure sputtering process carried out in a chamber with a pressure set in a range of about 1 to 5 millitorr and has a thickness of about 200 to 700 Angstroms. In another embodiment, the first molybdenum layer is formed with internal tensile strain. Depending also on the sputtering power and substrate temperature, other than the low-pressure condition, the first molybdenum layer 106 can be formed under tensile stress ranging from 300 MPa to 1000 MPa. One advantage of the tensile stress in that portion of the film is to help retaining film integrity when a patterning process using mechanical scribing or laser ablation techniques is performed to scribe a trench for forming a cell line boundary. As the molybdenum is partially removed, the remaining (major) portion of the molybdenum can stay strongly attached to the substrate, serving as an electrode for the particular cell. Other materials, including transparent conductor oxide (TCO) such as indium tin oxide (commonly called ITO), florine doped tin oxide (FTO), and the like can be used for the back electrode.

Referring to FIG. 1, a second molybdenum layer 108 is formed over the first molybdenum layer 106. The second molybdenum layer 108 is characterized by a compressive internal strain formed in another sputtering deposition process carried out with a chamber pressure between 10 millitorr and 20 millitorr, to have a thickness range of about 2000 Angstroms to 7000 Angstroms. Depending on the pressure, sputtering power, and temperature, the second molybdenum layer 108 is formed under compressive stress ranging from stress neutral to −200 MPa. In a preferred embodiment, the compressive stress within the second molybdenum layer 108 facilitates a self repairing of the film cracking or shallow edge void within the first molybdenum layer 305 around the cell line boundaries formed during the patterning process.

In an alternative embodiment, the bi-layer electrode process can be performed using the following conditions. The process for forming the first molybdenum layer 106 can be done at a low pressure of around 1-5 mtorr and a lower sputtering power of about 1-4 kW. The subsequent process for forming the second molybdenum layer 108 then uses high pressure about 10-20 mtorr combined with high sputtering power of about 12-18 kW. The thickness of each layer can be similar to that described above.

Other options for processing can be utilized. For example, the pressure of the chamber can be kept constant for both sputtering processes. But the sputtering power can be set to 1-4 kW for the first molybdenum layer 106 and increased to high at about 12-18 kW for the second molybdenum layer 108. Of course, there can be other variations, modifications, and alternatives. For example, the first layer can be deposited at low power and high pressure, with the second layer at high power, but low pressure. The stress nature of the bi-layer film structure is modified, but the first layer still is in tension and the second layer in compression. Alternatively, the first molybdenum layer 106 can be replaced by another material such as titanium. The thickness of the titanium layer can be about 300 Angstroms. Furthermore, a titanium underlayer can be optionally added before the first molybdenum layer is formed.

Referring to FIG. 1, a photovoltaic absorber material 110 is formed overlying the second molybdenum layer 108. In an embodiment of the present invention, the photovoltaic absorber material 110 is a copper-indium-gallium-diselenide (CIGS) compound material formed based on a two-step process including a physical vapor deposition of a thin-film precursor material followed by a two-stage reactive thermal treatment of the thin-film precursor material. In another embodiment, the CIGS compound material formed via the two-step process comprises a plurality of grains with well-crystallized chalcopyrite structure of CuInGaSe₂ or CuInGa(SSe)₂ in a size of about 0.75 microns having a preferred Cu/(In+Ga) composition ratio of about 0.9. Physically, the CIGS absorber has a thickness of about 1-2 microns. Electrically, it is characterized by a p-type semiconductor electric property and an energy band gap ranging from less than 1 eV to about 1.1 eV. In a specific implementation of the present invention, the CIGS material exhibits excellent photovoltaic absorption of sunlight spectrum at least partially over a spectrum portion from red to infrared range and converts absorbed photons into electrons with high efficiency. The high efficiency partially results from an optimized grain sizes around 0.75 microns via the two-step process, which facilitate light absorption to generate large quantity of photo-electrons and support quick delivery the photo-electrons to the emitter. In an embodiment, the gallium species may be eliminated during the preparation of the thin-film precursor material so that the resulted photovoltaic absorber comprises mainly copper-indium-diselenide material, namely a CIS absorber material. In another specific embodiment, the energy band gap value is tuned to have the CIGS/CIS photovoltaic absorber material being best for serving a bottom device of a multi junction cell.

Following the photovoltaic absorber material 110 with p-type characteristic, an n-type doped emitter material is formed to have a complete p-n junction for generating electricity from the light absorption. Then n-type buffer material 120 is deposited overlying the absorber 110. The buffer material 120 is preferably a chemically deposited Cadmium Sulfide (CdS) layer with a mild n-type doping, a wider energy band gap than the CIGS absorber material, and fine grains in micro or nano-crystalline structure. The buffer material 120 CdS layer is formed using chemical bath deposition by dipping the whole glass substrate bearing all the thin-films formed previously and having a CIGS absorber surface into a heated bath provided with an aqueous solution, which includes at least a cadmium species, an ammonia species, and an organosulfur species.

In a specific embodiment, the cadmium species can be derived from various cadmium salts such as cadmium acetate, cadmium iodide, cadmium sulfate, cadmium nitrate, cadmium chloride, cadmium bromide, and others. One purpose of using Cadmium is to utilize strong n-type donor characteristic of Cd in association with the CIGS absorber material. During the chemical bath process, a region with a depth of about 0.1 microns near the CIGS absorber surface acquires Cd species (bonded with Sulfur species) to become a buffer layer, changed from a p-type or an intrinsic characteristic to a n-type characteristic. The n-type character buffer material 120 at least partially serves as a photovoltaic window material for a single junction thin-film photovoltaic cell. More detail descriptions about the buffer material processing for fabricating thin-film photovoltaic material can be found in U.S. patent application Ser. No. 12/569,490 titled “Large Scale Chemical Bath System and Method for Cadmium Sulfide Processing of Thin Film Photovoltaic Materials” filed in Sep. 29, 2009 by Robert D. Wieting, commonly assigned to Stion Corporation, San Jose, Calif., which is fully incorporated as references for all purposes.

Referring to FIG. 1 again, a transparent conducting material 130 is formed overlying the buffering material 120 to serve mainly as an electrode for the thin-film photovoltaic cells. Typically, the transparent conducting material 130 is a transparent conductive oxide (TCO), such as In₂O₃:Sn (ITO), ZnO:Al (AZO), SnO2:F (TFO), but other materials that are optically transparency for sun light spectrum and have a sheet resistance of less than about 10 Ohms/square centimeter. In a specific embodiment, the transparent conducting material 130 is a bi-layer Zinc Oxide layer including a high resistance lower layer 131 and a low resistance upper layer 132. The Zinc Oxide ZnO layer is formed using a Metal-Organic Chemical Vapor Deposition (MOCVD) technique using a mixture of reactant gaseous species including a diethyl zinc material and an oxygen bearing species. The oxygen bearing species can be water vapor with the water to diethylzinc ratio of greater than about 1 to 4 in a specific embodiment. In another specific embodiment, a boron bearing species derived from a diborane gas/vapor also is added at a selected flow rate into the mixture of reactants.

The MOCVD process is performed in an enclosed chamber with controlled ambient pressures and properly configured substrate support fixtures and work gas supply system. The chemical reaction of the supplied reactant gaseous species occurs near a substrate at an elevated temperature to cause a deposition of a boron-doped zinc oxide material overlying the buffer material. By adjusting a flow rate of diborane species, the Boron doping level in the ZnO layer as formed can be adjusted so that the high resistance lower layer 131 can be formed first overlying the buffer material 120. Followed that, the flow rate of diborane species can be increased from substantially zero to a high value depended on specific system so that the low resistance upper layer 132 is formed. In an embodiment, the low resistance upper layer 132, which is subjected to a heavy Boron doping, is preferably characterized by an optical transmission greater than about 90 percent and small resistivity of about 2.5 milliohm-cm and less. In the implementation, the low resistance upper layer serves directly as an electrode layer for the photovoltaic cell. The high resistance lower layer 131, which has low or no Boron doping and a high resistance ranging from 1 ohm per square to 1 milliohm per square, becomes a partial portion of the window material 120 by forming a good ohmic contact between the n-type CdS layer and the low resistance upper layer 132. The high resistance lower layer 131 still has a good optical transparence property with at least an optical transmission greater than about 80 percent. In other words, the high resistance lower layer 131 is a high resistive transparent (HRT) layer serving as a buffer between the window layer of pn junction cell and an overlying transparent conductive (electrode) layer. The HRT layer serves as a protection layer which can substantially reduce electric shorting or carrier recombination by potential pinholes or whiskers formed at the interface between the electrode layer and the photovoltaic material. The high efficiency single junction thin-film photovoltaic cell relies on the formation of photovoltaic absorber material using a two-step process. In particular, the two-step process starts with a physical vapor deposition (sputter or evaporation technique) of a thin-film precursor at relative low temperature (T<200° C.).

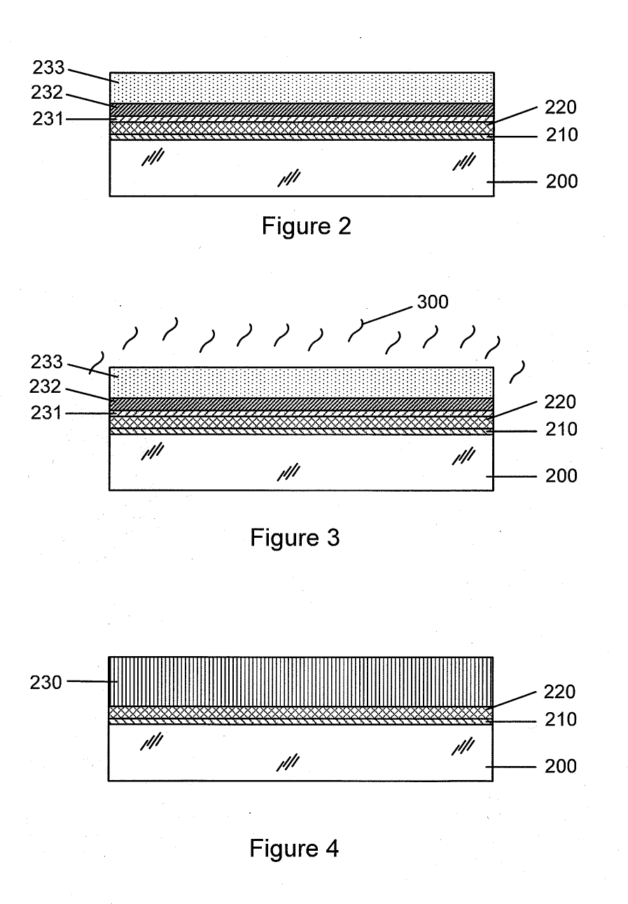

FIG. 2 is a simplified diagram illustrating a precursor composite material formed overlying the electrode by sputtering processes according to embodiments of the present invention. As shown in an example for forming a copper-based precursor material, at least three layers of precursor material are formed one after another. First, a sodium bearing material 231 is deposited over a back electrode 220 on a glass substrate 200. Between the back electrode 220 and a surface of the glass substrate 200, a barrier material 210 can be inserted. The sodium bearing material 231 mainly serves as a source of sodium species for mixing or diffusing throughout thin-film precursor material (to be formed later) for assisting the formation of a copper-based photovoltaic absorber.

In an example, a sputter technique is applied for depositing the sodium bearing material 231 using a sodium bearing target device with a specifically determined composition and purity of several element species including sodium, copper, gallium, and others. The sputtering process can be carried out in a chamber pre-pumped down to a pressure in a range of a few mTorr before introduction of work gases including Argon gas and/or Nitrogen gas. In a specific embodiment, the sputtering process is initiated via DC magnetron with a power of 1.5 kW or higher. For example, a 1.75 kW power is applied for depositing the first precursor from the sodium bearing target device with Argon gas flow rate of about 200 sccm is used for controlling deposition rate throughout the deposition process. Correspondingly, a sodium area density associated with the deposition rate is determined to be in a range of 0.03 to 0.09 micromoles/cm². In an implementation, the sodium bearing precursor material formed by the above sputtering process has a film thickness of about 60 nm.

As shown in FIG. 2, a second layer of precursor material comprising copper-gallium alloy material 232 is formed overlying the sodium bearing material 231. Again, the deposition of the copper-gallium alloy can be done by sputtering at a relative low temperature (T<200° C.) in the same chamber or a different compartment of the chamber using an alternate Cu—Ga alloy target device. In an implementation, the Cu—Ga alloy target device used in the process contains 99.9% pure copper-gallium alloy, and particularly the copper-gallium composition ratio is preferred to be substantially equal to the copper-gallium composition ratio in the sodium bearing target device used earlier. One advantage for matching the target composition is help to grow the second layer of precursor material smoothly on the sodium bearing precursor material (containing copper and gallium) and substantially without inducing interface lattice stress that may cause film cracks or other defects. DC magnetron sputtering technique is performed with power of about 4±1 kW applied to the Cu—Ga alloy target device and Argon gas flow rate set at about 170 sccm to control deposition rate for forming the Cu—Ga alloy material 232. In an example, a thickness of 120 nm of the Cu—Ga alloy material is deposited.

A third layer of precursor material including Indium species is formed after the formation of the Cu—Ga alloy material. As shown in FIG. 2, indium material 233 is over the Cu—Ga alloy material 232, deposited using DC magnetron sputtering technique. The deposition can be performed in a different compartment of the chamber using a pure 99.99% Indium target device. In an example, the Ar flow rate during the deposition is set to about 100 sccm and the DC power used for sputtering is about 9.2 kW. The indium deposition rate determines a mole density of about 1.84 micromoles/cm² for the indium material 233 formed accordingly. In an example, an Indium layer with a thickness of about 290 nm is deposited. After formation of the first two layers of precursor material, Indium material deposition must be performed to ensure that a predetermined stoichiomistry of the whole thin-film precursor material including sodium bearing material 231, Cu—Ga alloy material 232, and the indium material 233 is reached in a desired range and well controlled. For example, the stoichiometry can be characterized by a CIG ratio referring as a composition ratio of cupper species over combined indium species plus gallium species among the whole thin-film precursor material formed in above sputtering processes. In an example, the CIG ratio is in a range of 0.85 to 0.95. According to certain embodiments, the CIG ratio near 0.9 is a preferred composition ratio for causing a formation of the copper-based photovoltaic absorber material that produces high efficiency solar conversion. The two-step process for forming the photovoltaic absorber material includes a high temperature annealing of the thin-film precursor material formed by low temperature deposition.

FIG. 3 is a diagram illustrating a thin-film precursor material being treated for fabricating a photovoltaic absorber material according to an embodiment of the present invention. As shown, the glass substrate 200 including the thin-film precursor material (231, 232, 233) is disposed in an environment to subject a thermal treatment 300. In a specific embodiment, for the copper-based thin-film precursor material including sodium species, copper species, gallium species, and indium species, the thermal treatment 300 is a reactive annealing process in a heated gaseous environment to cause the thin-film precursor material to react with one or more reactant gases.

In particular, the high temperature reactive annealing process can be performed in a furnace chamber configured to include reactant gases mixed with inert gas and to be heated based on a predetermined temperature profile. In an implementation for treating the copper based thin-film precursor material, the reactant gas includes a selenium species and sulfur species. For example, hydrogen selenide gas plus nitrogen gas is supplied at least for one annealing stage and hydrogen sulfide gas plus nitrogen gas is supplied for another annealing stage. In an embodiment, the furnace chamber includes one or more heaters to supply thermal energy to heat the chamber and raise a temperature of a glass substrate bearing the thin-film precursor material loaded therein. The heaters are disposed spatially around the furnace chamber and are capable of being operated independently to ensure the temperature of the glass substrate substantially uniformly. In a specific embodiment, multiple large glass substrates with a form factor of 165×65 cm are loaded for the reactive annealing process for fabricating the high efficiency photovoltaic module. In an example, the predetermined temperature profile includes a first temperature ramping stage to raise temperature from room temperature quickly to a first dwelling stage where the thin-film precursor material is annealed within a first process temperature range. At the first dwelling stage, selenium gas species are filled in ambient of the chamber as a major reactant. Then following the predetermined temperature profile, a second ramping stage further raises temperature quickly to a second dwelling stage where the thin-film precursor material is additionally annealed at a higher process temperature range. At this stage, sulfur species is filled in as a major reactant while selenium species is at least partially removed. Both the annealing processes substantially cause the transformation of the copper-based thin-film precursor material (231, 232, 233) to a composite material with sodium species diffused and selenium/sulfur species incorporated throughout. Following that, the furnace chamber can be cooled down and the composite material formed in a particular crystalline structure with desired grain sizes becomes a material with desired opto-electrical properties as a high efficiency photovoltaic absorber.

FIG. 4 is a diagram illustrating a formation of the photovoltaic absorber material. As shown, a glass substrate 200 has an overlying barrier layer 210 and a back electrode 220 is formed overlying the barrier layer 210. After the high temperature reactive annealing process, the photovoltaic absorber material 230, which is transformed from the thin-film precursor material (231, 232, 233), is formed overlying the back electrode 220. In an embodiment, the photovoltaic absorber material includes copper, indium, gallium, and selenium species and forms in a plurality of crystalline grains one next to another. Particularly, each grain contains a copper-indium-gallium-diselenide (CuInGaSe₂) or copper-indium-gallium-disulfide (CuInGaS₂) or their mixed form CuInGa(SeS)₂. These materials are referred as CIGS thin-film photovoltaic absorber. In certain embodiments, gallium species may be removed from the processes so that a CIS thin-film photovoltaic absorber is resulted.

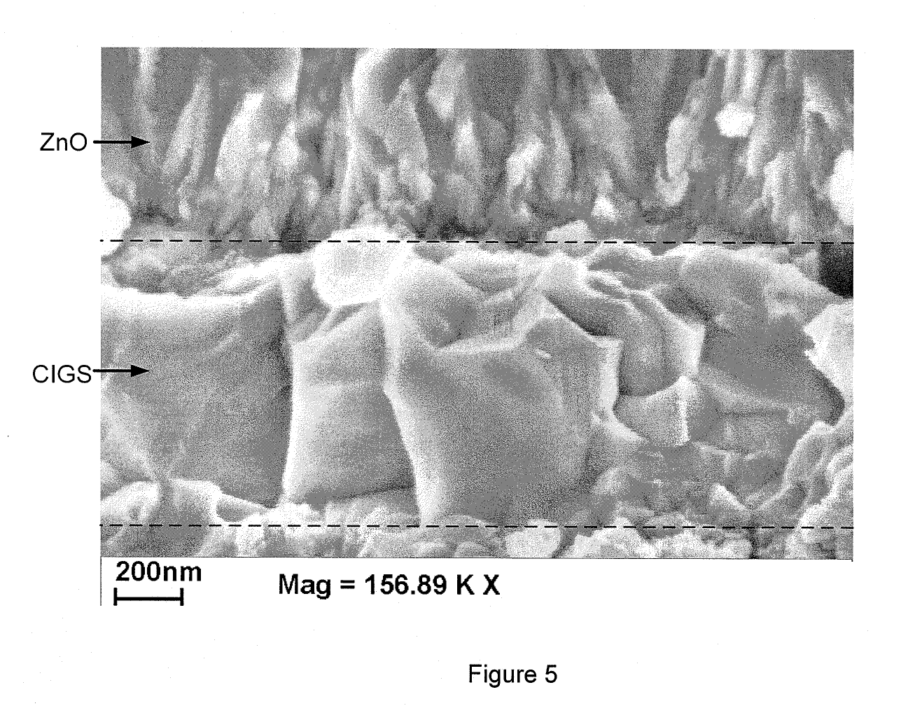

FIG. 5 is an exemplary SEM image of grain structures of CIGS thin-film photovoltaic absorber and upper electrode layer according to an embodiment of the present invention. As shown in the cross section view, the CIGS absorber is formed with well developed, compact grains extended substantially in a vertical column shaped form through the thickness of the absorber film. The average grain size is about 0.75 microns although it is not easily decipherable from the cross section image because of the artifacts introduced at cleaving. In a specific embodiment, the addition of sodium species in the thin-film precursor material in terms of proper selection of a sodium-bearing sputter target and subsequent sputter deposition conditions as well as the reactive thermal treatment conditions substantially determines the final grain structure of the CIGS/CIS absorber. And, the grain structure of the absorber plays one of key roles to improve photovoltaic conversion efficiency of the thin-film solar module. Of course, there are many alternatives, variations, and modifications.

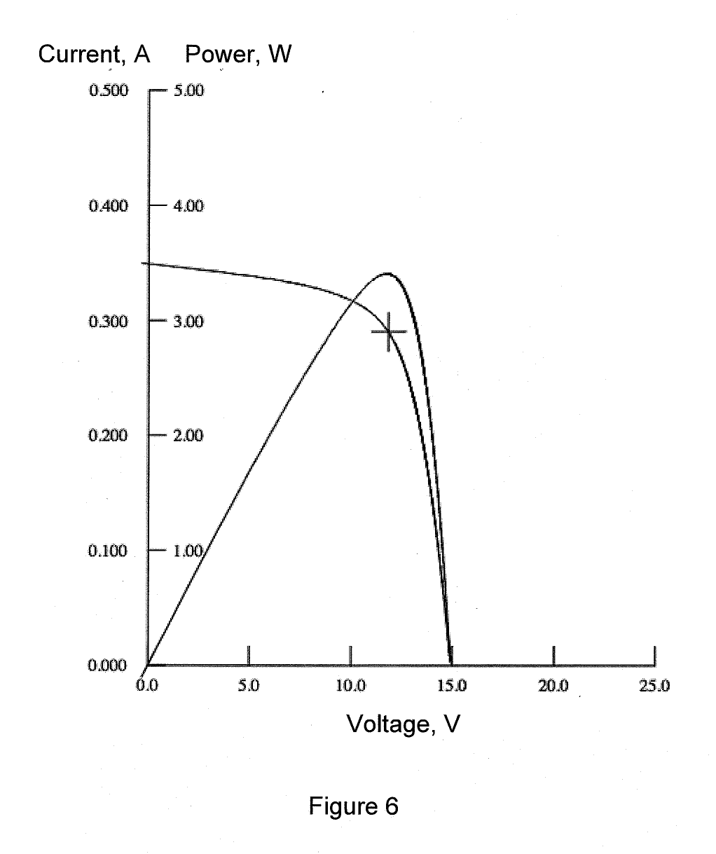

FIG. 6 is an exemplary IV characteristic diagram illustrating record efficiency for a sample CIGS photovoltaic module according to an embodiment of the present invention. In this example, the sample solar cell is formed with a copper-indium-gallium-diselenide CIGS absorber material having an energy band-gap of about 1.05 eV. In this plot, the photo-electron current generated by the sample solar cell is plotted against bias voltage. Also the cell power (calculated) is plotted against the voltage. Based on the data and a standard formula, a cell conversion efficiency η can be estimated:

$$η = \frac{{J}_{SC} \cdot {V}_{OC} \cdot FF}{{P}_{in} ( AM 1.5 )}$$

where J_{SC} is the short circuit current density of the cell, V_{OC} is the open circuit bias voltage applied, FF is the so-called fill factor defined as the ratio of the maximum power point divided by the open circuit voltage (Voc) and the short circuit current (J_{SC}). The fill factor for this device is 0.66. The input light irradiance (Pᵢₙ, in W/m²) under standard test conditions [i.e., STC that specifies a temperature of 25° C. and an irradiance of 1000 W/m² with an air mass 1.5 (AM1.5) spectrum.] and the surface area of the solar cell (in m²). The short-circuit current density J_{SC} is deduced to be about 33.9 mA/cm² and the open circuit voltage is measured to be about 0.55 V. This yields an efficiency of about 12.3% for the sample device.

The high efficiency single junction CIGS thin-film photovoltaic cell can be applied to form part of a multi junction solar module. In particular, the single junction cell comprises a CIGS based absorber having a band gap energy about 1 eV to 1.1 eV. The single junction cell is suitable as a bottom device that can be coupled to a top device with an absorber having a wider band gap to form a two junction tandem cell.

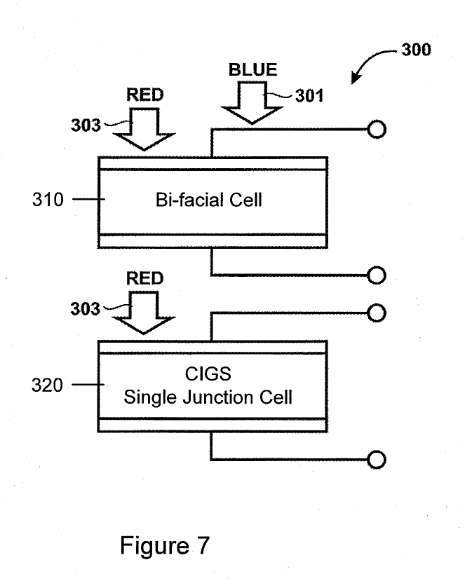

FIG. 7 is a simplified diagram illustrating an optional application of a CIGS photovoltaic cell as a bottom device coupled with a top bi-facial device for forming a tandem module according to an embodiment of the present invention. As shown, the module 300 with a multi junction tandem cell structure includes at least a top device 310 coupled to a bottom device 320. In an example, the top device 310 is a bi-facial cell including a pn junction with an absorber material having a desired energy band-gap about 1.6 to 1.9 eV or larger. The junction of the bi-facial cell can be sandwiched by transparent conductor oxide (TCO) electrodes with a similar energy band-gap, a proper optical transmittance, and good electric conductivity. The band gap of this junction preferably allows light absorption of a “Blue” band 301 of the sunlight spectrum to convert to a first portion of photoelectron current while allows a “Red” band 303 of the sunlight spectrum passing through. The filtered red band 303 of sunlight spectrum is then mostly able to reach at the CIGS absorber of a bottom device 320 through a transparent upper electrode, although some percentage of light intensity for this spectrum has been lost. The CIGS absorber, as described earlier, has a desired energy band-gap of about 0.7 to 1.1 eV. Therefore, the CIGS absorber can capture the red band light 303 at least partially and convert to a second portion of photoelectron current. Each of the top device 310 and bottom device 320 has two electric terminals for outputting the photoelectron current. Depending on application, the tandem module can be configured to a 4-terminal one, 3-terminal one, or a 2-terminal one for enhancing overall conversion efficiency. Of course, there are many variations, alternatives, and modifications. With continuing improvement in thin-film deposition process, thermal treatment process, as well as lamination process, the photovoltaic conversion efficiency of the CIGS/CIS thin-film solar module can be enhanced further to 14% or 15% or higher.

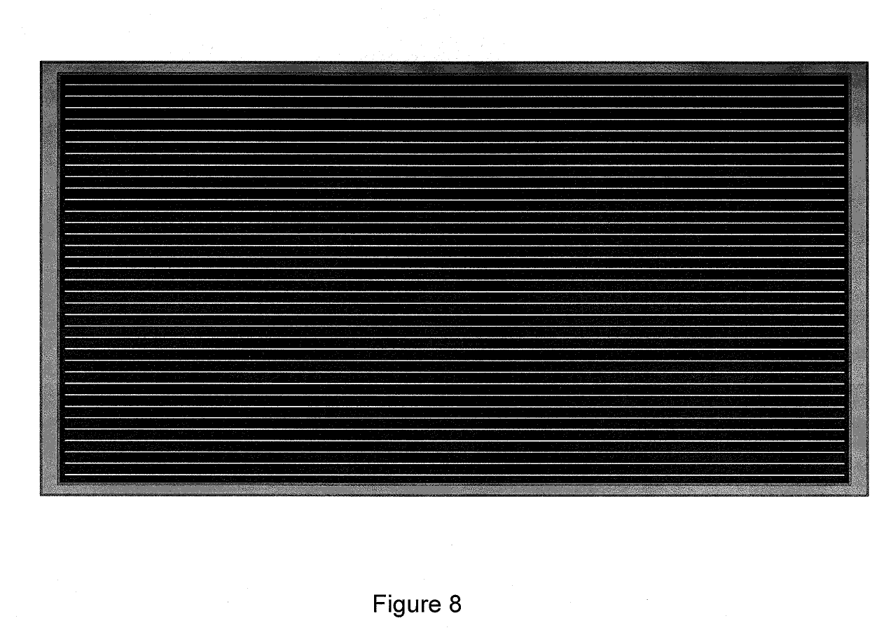

In an alternative embodiment, the method for manufacturing high efficiency photovoltaic module includes laminating the tandem module containing a top device coupled over a bottom device. FIG. 8 is a schematic diagram illustrating a top view of a laminated sample CIGS photovoltaic module according to an embodiment of the present invention. As shown, the laminated module has a rectangular shape with a form factor of 165 cm×65 cm. Through a top cover glass multiple stripe shaped cell line patterns can be seen. The lamination is a fully monolithic integration of a plurality of thin-film photovoltaic cells formed and patterned on a glass substrate. Thus, no process is required for stringing, tabbing, screen print, cell sorting and assembly or testing of conventional 1×1 cells. Cell line patterning was performed using a mechanical scribing or laser ablation techniques in one or more corresponding steps during a series of thin-film processes. Patterning is performed after a back electrode layer is formed, or after the CIGS absorber material is formed, as well as after an upper electrode layer is formed. This eliminates a lot of interconnects or solder joints used in conventional-type Si-based module during the module assembly. The dimensions and other packaging details of the panel can be easily customized for application specific PV project. For example, the same form factor and module lamination can be applied to form a tandem photovoltaic module with a top device coupled with the CIGS single junction bottom device. In a specific embodiment, the top-bottom coupling material can be an ethylene vinyl acetate, commonly called EVA, poly vinyl acetate, commonly called PVA, and others. The coupling can be electrically in series so that higher cell voltage level can be provided. Or the coupling can be electrically in parallel so that the first electric current converted by the bottom device is added to the second electric current converted by the top device. All these advantages help to achieve a substantially improved module reliability and a much narrower performance distribution in mass production of the thin-film photovoltaic modules.

In a specific embodiment, the present invention also provide a method for manufacturing a high efficiency thin-film photovoltaic module. The method includes supplying a substrate having a dimension of a length of about 2 feet and greater times a width of about 5 feet and greater. The substrate typically uses glass such as soda-lime glass, an acrylic glass, a sugar glass, a specialty Corning™ glass, a quartz, and even a plastic, and others. The form factor of 165 cm×65 cm is one of the largest available in the solar module industry. After one or more surface cleaning process, the method includes forming a barrier material overlying a surface region of the substrate. The barrier material can be a thin layer of silicon oxide deposited using physical vapor deposition, evaporation, or chemical vapor deposition. Then the method includes forming a conductive material overlying the barrier material. The conductive material can be a metal, metal alloy, conductive oxide, or others, for forming a back electrode of the to-be-formed photovoltaic module. In an example, the conductive material is molybdenum deposited using sputter technique.

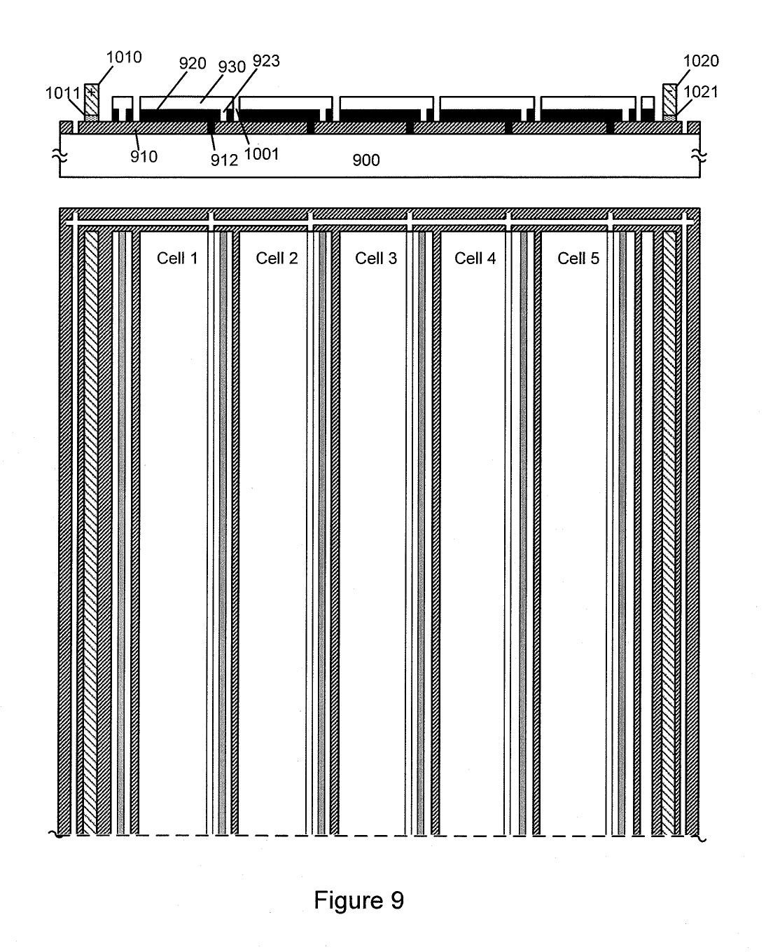

So far, all the thin-film material can be formed overlying all surface regions of the substrate. Then, a thin-film patterning process can be performed through the conductive material. FIG. 9 is a simplified diagram of a cross sectional view and a corresponding top view of a single junction CIGS thin-film photovoltaic module with multiple patterned stripe shaped cells according to an embodiment of the present invention. The glass substrate 900 is provided for manufacturing the single junction thin-film photovoltaic module. A conductive material 910 is formed throughout surface of the substrate 900 and a patterning process is performed to scribe through the conductive material 910 to form a plurality of linear trenches 912 with a substantially equal spacing. These trenches 912 form boundaries of a plurality of stripe shaped regions. For example, as shown in FIG. 9, each stripe shaped region leads to a formation of a photovoltaic cell. In a specific embodiment, the cell trenches are formed using a mechanical scriber or multiple scribers to scribe across the surface one linear trench every 6.1 mm and down to a depth that is a little more than a thickness of the conductive material 910 but not through a barrier material (not shown explicitly) formed underneath the conductive material 910. Basically the plurality of the scribed linear trenches divide the thin-film on the substrate into a plurality of regions and each region becomes a basis for forming a photovoltaic cell and the conductive material remained in each region becomes a first electrode of each cell.

Additionally, the method for manufacturing the high efficiency thin-film photovoltaic module includes forming a precursor material overlying the first electrode of each cell. The precursor material includes materials deposited one after another including a sodium-bearing material, a copper-gallium alloy material, and an indium material. The method further includes treating the precursor material in a gaseous environment comprising at least selenium species and sulfur species based on a predetermined temperature profile. The treating process is a reactive thermal annealing process for transforming the precursor material into an absorber material. In particular, the precursor material containing sodium, copper, gallium, and indium species reacts with selenium species and/or sulfur species during the treatment, leading to a formation of a copper-indium-gallium-diselenide compound material which bears substantially a structure of plurality of column shaped chalcopyrite crystalline grains. The copper-indium-gallium-diselenide compound material is characterized by a p-type electrical characteristic with an energy band-gap of about 1 eV to 1.1 eV, which is essential to be a desired photovoltaic absorber for absorbing at least a partial sunlight spectrum. The whole absorber material bears a preferred Cu/(In+Ga) composition ratio of about 0.9 obtained through a stoichiometry control during both the precursor deposition and the reactive thermal treatment, which at least partially determines the absorber's grain structure, electrical property, and optical property. Of course, there can be many variations, alternatives, and modifications.

Furthermore, the method includes forming a buffer material overlying the absorber material. The buffer material comprises an n-type characteristic and optically transparent with an energy band gap wider than the absorber material. Essentially, the n-type buffer material overlying the p-type absorber material forms a pn junction with the buffer material as an emitter capable of collecting electrons generated by photons absorbed in the absorber material. In an example, the buffer material is cadmium sulfide CdS material formed using a chemical bath deposition technique. The CdS buffer material is much thinner in thickness than the absorber material. In FIG. 9, such buffer material is not explicitly shown and the pn-junction is substantially represented by absorber 920. Following the formation of the pn-junction, another patterning process may be performed to scribe through the buffer material and the absorber material. A second plurality of linear trenches 923 is formed at positions respectively shifted a small distance from the first plurality of linear trenches 912. The small distance is substantially smaller than the cell width. Referring to FIG. 9, each second trench 923 removes a portion of the absorber/buffer material to allow a conducting material to be filled in for electric coupling one cell with a neighboring cell.

Moreover, the method includes depositing a transparent conductive material 930 overlying the buffer material and the second plurality of linear trenches. In an embodiment, depositing a transparent conductive material includes forming a high resistivity transparent material overlying the buffer material to complete a photovoltaic window material having a p-type electrical characteristic. In an implementation, the transparent conductive material is zinc oxide material doped by certain n-type impurity species. In a specific embodiment, MOCVD technique is used for depositing one or more zinc oxide layers over the buffer material. During the process, a diborone gas is supplied with a controlled flow rate to dope Boron into the zinc oxide layer. By reducing the Boron doping level, the first zinc oxide layer can be a high resistivity transparent material. This layer partially serves a physical barrier layer forming a good ohmic contact between photovoltaic junction material (absorber and buffer material) and an upper electrode material. It also bears an n-type semiconducting characteristic to serve as part of the photovoltaic window layer including the buffer material. Following that, the zinc oxide material can be further deposited under the same MOCVD process but with much higher Boron doping level. This leads to a formation of a transparent conductive material with much lower resistivity. Moreover, another patterning process can be carried to scribe with a third plurality of linear trench 1001 through the transparent conductive material including both the low and high resistivity transparent materials. Each of the third trenches 1001 is shifted a small distance further from the second trench 923 and again is substantially smaller the lateral dimension of each cell. The remained portion of the transparent conductive material within each cell region separated by the linear trench 1001 becomes a second electrode or upper electrode of that cell. Each cell has been electrically coupled to each other through the coupling materials in the corresponding first trench 912 and second trench 923 formed earlier, either electrically in series or in parallel.

Finally, as shown in FIG. 9, a soldering material 1011 or 1021 is placed over an exposed portion of the conductive material overlying the substrate near each edge region in parallel to the stripe shaped cell. Correspondingly a conducting bus bar or tape 1010 or 1020 is respectively disposed over the soldering material in a soldering process. The conducting bus bar 1010 or 1020 forms respective cathode or anode electric lead of the whole photovoltaic module. Of course, there are many variations, alternatives, and modifications. For example, the method for manufacturing the thin-film photovoltaic module may further include additional electric circuit finishing and module packaging including dispose a cover glass over the second electrode coupled to the second electrode via a coupling material selected from an ethylene vinyl acetate (EVA) and poly vinyl acetate (PVA). In another example, the method may include panel framing for the large sized substrate (and cover glass) having a length of 165 cm or greater and a width of 65 cm or greater and other module level treatments. In one or more examples, the thin-film photovoltaic module formed according to one or more embodiments of the current invention exhibit excellent performance in electric power generation by converting sun light into electricity with conversion efficiency superior to 15% or higher. Another alternative process may include coupling the just formed single junction photovoltaic module with another module configured to be a bi-facial module to form a multi junction module.

Although the above has been illustrated according to specific embodiments, there can be other modifications, alternatives, and variations. It is understood that the examples and embodiments described herein are for illustrative purposes only and that various modifications or changes in light thereof will be suggested to persons skilled in the art and are to be included within the spirit and purview of this application and scope of the appended claims.

What is claimed is:

1. A high efficiency thin-film photovoltaic module comprising:
a substrate having a surface with a length of about 2 feet and greater and a width of about 5 feet and greater;
a plurality of stripe shaped photovoltaic cells electrically coupled to each other and physically disposed in parallel to the length one next to another across the width, each cell comprising:
a barrier material overlying the surface;
a first electrode overlying the barrier material;
an absorber formed overlying the first electrode, the absorber comprising a copper gallium indium diselenide compound material characterized by an energy band-gap of about 1 eV to 1.1 eV;
a buffer material overlying the absorber; and
a bi-layer zinc oxide (ZnO) material comprising a high resistivity transparent layer overlying the buffer material and a low resistivity transparent layer overlying the high resistivity transparent layer, wherein the buffer material combining the high resistivity transparent layer comprises a photovoltaic window material for collecting photoelectrons converted by the photovoltaic absorber and the low resistivity transparent layer forms a second electrode; and
a first electric lead and a second electric lead formed respectively on the first electrode near each edge region of the substrate along the length.

2. The thin-film photovoltaic module of claim 1 wherein the substrate comprises a material selected from soda-lime glass, an acrylic glass, a sugar glass, a specialty Corning™ glass, a quartz, and a plastic.

3. The thin-film photovoltaic module of claim 1 wherein the barrier material comprises a dielectric material selected from silicon oxide, aluminum oxide, titanium nitride, silicon nitride, tantalum oxide, and zirconium oxide.

4. The thin-film photovoltaic module of claim 1 wherein the photovoltaic absorber is formed by using a thermal selenization and sulfurization process to treat a precursor comprising sodium bearing material, copper-gallium alloy material, and indium material in a gaseous environment including at least selenium and sulfur species.

5. The thin-film photovoltaic module of claim 1 wherein the photovoltaic absorber comprises a chalcopyrite structure having an average grain size of about 0.75 μm, a Cu/(In+Ga) composition ratio of about 0.9, and a n-type semiconducting characteristic.

6. The thin-film photovoltaic module of claim 1 wherein the first electrode comprises a conductive material selected from aluminum, gold, silver, molybdenum, molybdenum selenide, combinations thereof and a transparent conductor oxide.

7. The thin-film photovoltaic module of claim 1 wherein the buffer material comprises a cadmium sulfide (CdS) layer.

8. The thin-film photovoltaic module of claim 1 wherein the photovoltaic window material comprises a pyramid-like texture with a feature size of about 0.2 microns and a p-type semiconducting characteristic formed using a metal-organic chemical vapor deposition process.

9. The thin-film photovoltaic module of claim 1 wherein the second electrode comprises a resistivity of about 1 mΩ·cm, a surface characteristic of a pyramid-like texture having a feature size of about 0.2 microns, and an optical transmission of 90% at least for wavelengths ranging from 630 nm to 750 nm, formed using a metal-organic chemical vapor deposition process.

10. The thin-film photovoltaic module of claim 1 wherein the high resistivity transparent layer overlying the buffer material comprises a resistivity of 10² to 10⁴ mΩ·cm causing a formation of an ohmic contact between the photovoltaic window material and the second electrode.

11. The thin-film photovoltaic module of claim 1 wherein each of the plurality of stripe shaped photovoltaic cells comprises a photovoltaic conversion area having a lateral dimension of about 6.1 mm and a length substantially equal to the length of the substrate.

12. The thin-film photovoltaic module of claim 1 wherein each of the first electric lead and the second electric lead comprises a copper bus bar soldered on an Indium-Silver alloy contact coupled overlying the first electrode.

13. The thin-film photovoltaic module of claim 1 further comprising a cover glass coupled to the second electrode via a coupling material selected from an ethylene vinyl acetate (EVA) and poly vinyl acetate (PVA).

14. The thin-film photovoltaic module of claim 1 further comprising a NREL calibrated photovoltaic conversion efficiency ranging from 12% to 15% and greater.

15. A method for manufacturing a high efficiency thin-film photovoltaic module, the method comprising:
supplying a substrate having a dimension of a length of about 2 feet and greater times a width of about 5 feet and greater;
forming a barrier material overlying the substrate;
forming a conductive material overlying the barrier material;
scribing through the conductive material with a substantially equal spacing to form a plurality of stripe shaped cells, the conductive material remained within each stripe shaped cell comprising a first electrode;
forming a precursor material overlying the first electrode, the precursor material including a sodium-bearing material, a copper-gallium alloy material, and an indium material;
treating the precursor material in a gaseous environment comprising at least selenium species and sulfur species based on a predetermined temperature profile to form an absorber material characterized by a p-type electrical characteristic with an energy band-gap of about 1 eV to 1.1 eV and Cu/(In+Ga) ratio of about 0.9;
forming a buffer material having n-type characteristic overlying the absorber material having the p-type characteristic to form a pn junction;
patterning the absorber material and buffer material for coupling each stripe shaped cell with a neighboring stripe shaped cell;
forming a high resistivity transparent material overlying the buffer material;
forming a transparent conductive material overlying the high resistivity transparent material; and
patterning the transparent conductive material, the buffer material, and the absorber material to form a second electrode for each stripe shaped cell.

16. The method of claim 15 further comprising attaching at least one conductive tape near one edge of the substrate to couple with either the first electrode or the second electrode as a cathode or an anode of the thin-film photovoltaic module.

17. The method of claim 15 wherein the substrate comprises a material selected from soda-lime glass, an acrylic glass, a sugar glass, a specialty Corning™ glass, a quartz, and a plastic.

18. The method of claim 15 wherein the barrier material comprises a dielectric material selected from silicon oxide, aluminum oxide, titanium nitride, silicon nitride, tantalum oxide, and zirconium oxide.

19. The method of claim 15 wherein the forming a first electrode comprises depositing molybdenum using a sputtering technique to form a bi-layer structure respectively in tensile and compressive strains overlying the barrier material.

20. The method of claim 15 wherein the forming a precursor overlying the first electrode comprises performing thin film depositions using a sputtering technique over respectively a first target device comprising Na₂SeO₃ compound mixed with copper and gallium species, a second target device comprising Copper-Gallium alloy, and a third target device comprising substantially pure Indium.

21. The method of claim 15 wherein the patterning the first electrode to form a plurality of stripe shaped cells comprises dividing the substrate into a plurality of photovoltaic conversion regions each having a lateral dimension of about 6.1 mm and a length substantially equal to the length of the substrate.

22. The method of claim 15 wherein the forming a buffer material comprising depositing a Cadmium Sulfide material using a chemical bath deposition technique.

23. The method of claim 15 wherein the forming a high resistivity transparent material comprises performing a chemical vapor deposition process to form a Zinc Oxide layer doped with a light dosage of Boron characterized by a resistivity of 10² to 10⁴ mΩ·cm and an optical transparency of about 90% at least for wavelengths ranging from 630 nm to 750 nm.

24. The method of claim 15 wherein the forming a transparent conductive material comprises performing a chemical vapor deposition process to form a Zinc Oxide layer doped with beavy dosage of Boron characterized by a pyramid like texture throughout the layer with a resisitivity of a few mΩ·cm and an optical transparency of about 90% at least for wavelengths ranging from 630 nm to 750 nm.
